(19) United States
(12) Patent Application Publication
(10) Pub. No.: US 2009/0053905 A1
(43) Pub. Date: Feb. 26, 2009

(54) METHOD OF FORMING DIELECTRIC LAYER OF SEMICONDUCTOR MEMORY DEVICE

(75) Inventor: Jae Mun Kim, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (TW)

(21) Appl. No.: 12/147,232

(22) Filed: Jun. 26, 2008

(30) Foreign Application Priority Data
Aug. 20, 2007 (KR) 10-2007-0083355

(51) Int. Cl. H01L 21/469

(52) U.S. Cl. 438/785; 257/E23.077

(57) ABSTRACT

The invention relates to a method of forming a dielectric layer of a semiconductor memory device. According to an aspect of the invention, the method includes forming a high-k layer over a semiconductor substrate, and performing a plasma treating the high-k layer at a temperature less than the temperature in which the high-k layer would crystallize.

### CROSS-REFERENCE TO RELATED APPLICATION

Priority to Korean Patent Application No. 10-2007-0083355, filed on Aug. 20, 2007, the disclosure of which is incorporated by reference in its entirety, is claimed.

### BACKGROUND OF THE INVENTION

1. Field of the Disclosure

The invention relates to a method of forming a dielectric layer of a semiconductor memory device and, more particularly, to a method of forming a dielectric layer of a semiconductor memory device, that can improve the electrical properties of the semiconductor memory device.

2. Brief Description of Related Technology

A flash memory device is described below as an example. In general, a flash memory device has a stack structure of a tunnel insulating layer, a floating gate, a dielectric layer, and a control gate, which are formed over a semiconductor substrate. The tunnel insulating layer and the dielectric layer function to isolate the floating gates. More specifically, the tunnel insulating layer controls tunneling of electrons between the semiconductor substrate and the floating gate, and the dielectric layer controls coupling between the floating gate and the control gate.

The dielectric layer has a structure in which a first insulating layer, a second insulating layer, and a third insulating layer are sequentially stacked. The first and third insulating layers are formed of an oxide layer, and the second insulating layer is formed of a nitride layer. After the nitride layer is formed, an annealing process is performed to make the film quality of the nitride layer uniform. However, at the time of the annealing process, the nitride layer is likely to be crystallized due to the high annealing temperature, and thermal budget is likely to occur in the tunnel insulating layer. Further, if the nitride layer is crystallized, a leakage current is easily generated in the semiconductor memory device, which may degrade the electrical properties of the device.

### BRIEF SUMMARY OF THE INVENTION

The invention is directed to a method of forming a dielectric layer of a semiconductor memory device, in which the dielectric layer formed between a floating gate and a control gate has a stack structure of first, second, and third insulating layers. The second insulating layer is formed of a high-k layer to improve the electrical properties of the semiconductor device, and a pre-treatment process is performed on the second insulating layer to make a surface of the second insulating layer uniform and to prevent the second insulating layer from crystallizing, to prevent a leakage.

According to a preferred embodiment, the method includes forming a high-k layer over a semiconductor substrate, and performing a plasma treatment process at a temperature less than a temperature in which the high-k layer would crystallize, to make a film quality of the high-k layer uniform.

According to another preferred embodiment, the method includes providing a semiconductor substrate over which a tunnel insulating layer, a first conductive layer, and an isolation layer are formed; forming a first insulating layer on the first conductive layer and the isolation layer; forming a second insulating layer on the first insulating layer; performing a plasma treatment process at a temperature less than a temperature in which the second insulating layer would crystallize, to make a film quality of the second insulating layer uniform; and forming a third insulating layer on the second insulating layer.

A second conductive layer can be further formed on the third insulating layer. The second insulating layer is formed of a high-k layer. The second insulating layer can be formed, for example, to a thickness of approximately 20 angstroms to approximately 150 angstroms using, for example, an atomic layer deposition (ALD) method.

The ALD method can be performed, for example, at a temperature of approximately 200 degrees Celsius to approximately 600 degrees Celsius, and includes repeatedly performing a unit cycle that includes a source gas injection process, a purge process, and a reaction gas injection process.

The reaction gas can include, for example, any one of O₂, H₂O, O₃, or a mixed gas thereof. The high-k layer can be formed of any one of Al₂O₃, HfO₂, ZrO₂, SiON, La₂O₃, Y₂O₃, TiO₂, CeO₂, N₂O₃, Ta₂O₅, BaTiO₃, SrTiO₃, BST, and PZT, or by stacking two or more thereof.

The plasma treatment process can be performed, for example, using a plasma oxidization process employing a radical. The plasma oxidization process can be performed, for example, using a mix of Ar gas and O₂ gas. A H₂ gas can be further added to the mixed gas. The plasma oxidization process can be performed, for example, at a temperature of approximately 300 degrees Celsius to approximately 600 degrees Celsius, under a pressure of approximately 0.01 Torr to approximately 10 Torr, for example, and using a power of approximately 1 kW to approximately 5 kW, for example.

The first and second insulating layers can be formed, for example, of an oxide layer, and to a thickness, for example, of approximately 20 angstroms to approximately 50 angstroms. The oxide layer can be formed, for example, using a low-pressure chemical vapor deposition (LP-CVD) method and at a temperature range, for example, of approximately 600 degrees Celsius to approximately 900 degrees Celsius.

The oxide layer can be formed, for example, of a dichlorosilane high temperature oxide (DCS-HTO) layer by reacting SiCl₂H₂ and N₂O₂ gases with each other.

According to another embodiment, the method may include performing the plasma treatment process before forming the third insulating layer, to make a surface of the second insulating layer.

### BRIEF DESCRIPTION OF THE DRAWINGS

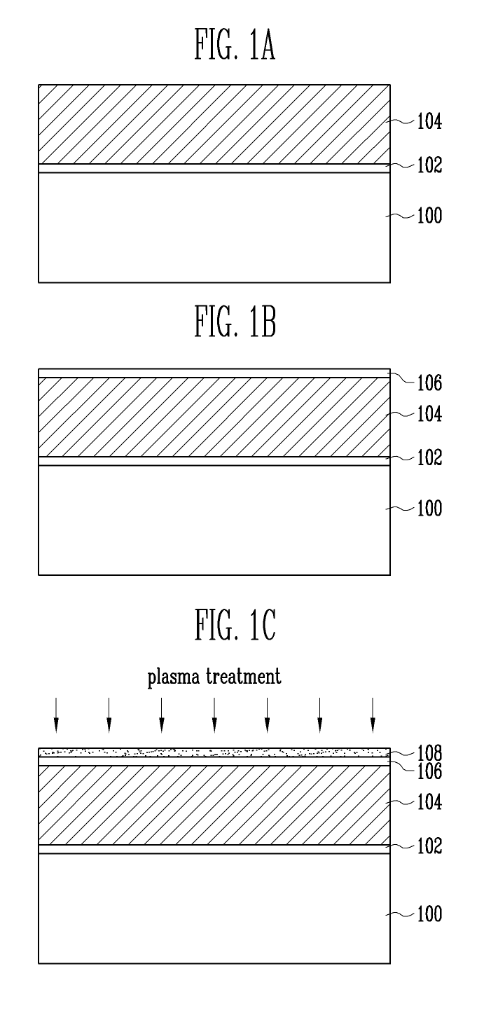

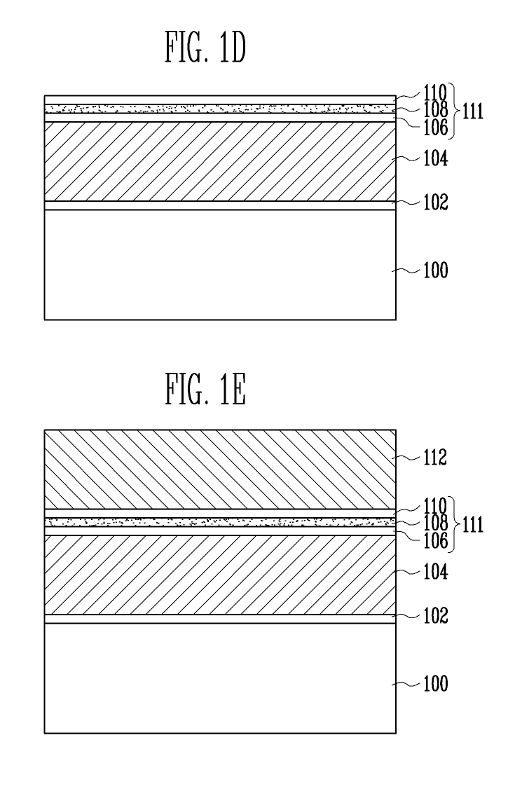

For a more complete understanding of the disclosure, reference should be made to the following detailed description and accompanying drawings. FIGS. 1A to 1E are sectional views illustrating a method of forming a dielectric layer of a semiconductor memory device according to the invention.

While the disclosed method is susceptible of embodiments in various forms, specific embodiments are illustrated in the drawings (and will hereafter be described), with the understanding that the disclosure is intended to be illustrative, and is not intended to limit the invention to the specific embodiments described and illustrated herein.

### DETAILED DESCRIPTION OF SPECIFIC EMBODIMENTS

Referring to FIG. 1A, a tunnel insulating layer 102 and a first conductive layer 104 for a floating gate are sequentially formed over a semiconductor substrate 100. The tunnel insulating layer 102 can be formed, for example, of an oxide layer, and the first conductive layer 104 can be formed, for example, of a polysilicon layer.

Trenches (not shown) are formed and an isolation layer (not shown) is formed within the trenches. The trenches (not shown) are formed by etching an exposed portion of the semiconductor substrate 100. The trenches (not shown) are then gap-filled with the isolation layer (not shown). Isolation mask patterns (not shown) are formed on the first conductive layer 104. The first conductive layer 104 and the tunnel insulating layer 102 are patterned by performing an etch process along the isolation mask patterns (not shown). The isolation mask patterns (not shown) are then removed. Next, the effective field oxide height (EFH) of the isolation layer (not shown) is controlled.

Referring to FIG. 1B, a first insulating layer 106 for a dielectric layer 111 (shown in FIGS. 1D and 1E) is formed on the first conductive layer 104. The first insulating layer 106 can be formed, for example, of an oxide layer. The first insulating layer 106 can be formed, for example, using a low-pressure chemical vapor deposition (LP-CVD) method. The LP-CVD method can be performed at a temperature of approximately 600 degrees Celsius to approximately 900 degrees Celsius. The first insulating layer 106 can be formed, for example, of a dichlorosilane high temperature oxide (DCS-HTO) product of a reaction between SiCl₂H₂ and N₂O₂ gases. The first insulating layer 106 can have, for example, a thickness of approximately 20 angstroms to approximately 50 angstroms.

Referring to FIG. 1C, a second insulating layer 108 is formed on the first insulating layer 106. The second insulating layer 108 can have a thickness of approximately 20 angstroms to approximately 150 angstroms using a high-k layer. The second insulating layer 108 can be formed, for example, using an atomic layer deposition (ALD) method. The high-k layer has a dielectric constant of approximately 3.9 or more and prevents the occurrence of the leakage current.

The ALD method is performed by separately injecting a source gas and a reaction gas. A purge process is performed between injections of the source gas and reaction gases to employ adsorption and desorption reactions. The source gas injection process, the purge process, and the reaction gas injection process are referred to herein as a “unit cycle.” The second insulating layer 108 can be formed by repeatedly performing the unit cycle.

The ALD method can be performed, for example, in a temperature range of approximately 200 degrees Celsius to approximately 600 degrees Celsius. The reaction gas can include, for example, any one of O₂, H₂O, O₃, and a mixture thereof. Various kinds of high-k layers can be formed depending on the type of the source gas. For example, the high-k layer can be formed of any one of Al₂O₃, HfO₂, ZrO₂, SiON, La₂O₃, Y₂O₃, TiO₂, CeO₂, N₂O₃, Ta₂O₅, BaTiO₃, SrTiO₃, BST, and PZT, or by stacking two or more thereof.

The high-k layer not only has an excellent film quality, but also an excellent step coverage characteristic when compared to a general nitride layer. Accordingly, if the second insulating layer 108 is formed of the high-k layer, a breakdown voltage can be raised, a shift of flatband voltage can be prevented, capacitance can be increased, and interference between cells can be reduced.

Furthermore, the high-k layer can be formed, for example, at a low temperature of approximately 200 degrees Celsius to approximately 600 degrees Celsius as described above. Therefore, damage, due to heat, of the tunnel insulating layer 102 can be prevented and reliability of a semiconductor device can be improved.

After the second insulating layer 108 is formed, a pre-treatment process is performed to make the film quality of the second insulating layer 108 uniform. For example, a plasma treatment process can be performed. The pre-treatment process is performed at a temperature lower than that of the prior art annealing process. For example, the pre-treatment process can be performed at a temperature of approximately 300 degrees Celsius to approximately 600 degrees Celsius. Accordingly, crystallization of the second insulating layer 108 can be prevented.

The plasma treatment process can be performed, for example, using a mix of Ar and O₂ gases, or a gas that includes H₂ gas. The plasma treatment process can be performed, for example, using a plasma oxidization process employing a radical. The plasma oxidization process employing a radical can be performed, for example, under a pressure of approximately 0.01 to approximately 10 Torr, using a power, for example, of approximately 1 kW to approximately 5 kW.

If the plasma treatment process is performed at a low temperature of approximately 300 degrees Celsius to approximately 600 degrees Celsius as described above, the high-k layer can maintain an amorphous thin film characteristic. Further, although a subsequent annealing process is performed at a high temperature of approximately 700 degrees Celsius to approximately 1000 degrees Celsius, the high-k layer is less crystallized by the plasma treatment process that is performed at a low temperature. Accordingly, a grain boundary path can be reduced and the occurrence of the leakage current can be prevented.

Referring to FIG. 1D, a third insulating layer 110 for a dielectric layer 111 is formed on the second insulating layer 108. The third insulating layer 110 can be formed, for example, of an oxide layer using, for example, a LP-CVD method. The LP-CVD can be performed, for example, at a temperature of approximately 600 degrees Celsius to approximately 900 degrees Celsius. The third insulating layer 110 can be formed, for example, of a DCS-HTO layer by reacting SiCl₂H₂ and N₂O₂ gases with each other. The third insulating layer 110 can be formed, for example, to a thickness of approximately 20 angstroms to approximately 50 angstroms.

The first, second, and third insulating layers 106, 108, and 110 form the dielectric layer 111.

Referring to FIG. 1E, a second conductive layer 112 for a control gate is formed on the dielectric layer 111. The second conductive layer 112 can be formed, for example, of a polysilicon layer or, for example, by stacking a polysilicon layer and a metal layer.

By forming the second insulating layer 108 of a high-k layer and performing the pre-treatment process on the second insulating layer 108, to prevent crystallization of the high-k layer, a leakage current characteristic and a charge retention characteristic can be improved, and a reduction of reliability of the tunnel insulating layer 102 due to thermal budget can be prevented. Further, the dielectric constant and the breakdown voltage can be increased, the shift of the flatband voltage can be prevented, capacitance can be increased, and interference between cells can be reduced.

The specific embodiments disclosed herein have been described for illustrative purposes. The person skilled in the art may implement the present invention in various ways. Therefore, the scope of the invention is not limited by or to the embodiments as described above, and should be construed to be defined only by the appended claims and their equivalents.

What is claimed is:

1. A method of forming a dielectric layer of a semiconductor memory device, the method comprising:
forming a high-k layer over a semiconductor substrate; and
performing a plasma treatment process at a temperature less than the temperature at which the high-k layer would crystallize, to make a film quality of the high-k layer uniform.

2. The method of claim 1, wherein the high-k layer is formed to a thickness of approximately 20 angstroms to approximately 150 angstroms.

3. The method of claim 1, wherein forming the high-k layer comprises performing an atomic layer deposition (ALD) method.

4. The method of claim 3, wherein the ALD method is performed at a temperature of approximately 200 degrees Celsius to approximately 600 degrees Celsius.

5. The method of claim 3, wherein the ALD method comprises repeatedly performing a unit cycle, the unit cycle comprising of a source gas injection process, a purge process, and a reaction gas injection process.

6. The method of claim 5, wherein in a reaction gas of the reaction gas injection process is selected from the group consisting of O₂, H₂O, O₃, and a mixture thereof.

7. The method of claim 1, wherein the high-k layer is formed of selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BST, and PZT, or by stacking two or more thereof.

8. A method of forming a dielectric layer of a semiconductor memory device, the method comprising:
forming a tunnel insulating layer, a first conductive layer, and an isolation layer over a semiconductor substrate;
forming a first insulating layer on the first conductive layer and the isolation layer;
forming a second insulating layer on the first insulating layer, wherein the second insulating layer is a high-k layer;
performing a plasma treatment process at a temperature lower than a temperature at which the second insulating layer would crystallize, to make a film quality of the second insulating layer uniform; and
forming a third insulating layer on the second insulating layer.

9. The method of claim 8, further comprising forming a second conductive layer on the third insulating layer.

10. The method of claim 8, wherein the second insulating layer has a thickness of approximately 20 angstroms to approximately 150 angstroms.

11. The method of claim 8, wherein forming the second insulating layer comprises performing an atomic layer deposition (ALD) method.

12. The method of claim 11, wherein the ALD method is performed at a temperature of approximately 200 degrees Celsius to approximately 600 degrees Celsius.

13. The method of claim 11, wherein the ALD method comprises repeatedly performing a unit cycle comprising a source gas injection process, a purge process, and a reaction gas injection process.

14. The method of claim 13, wherein a reaction gas of the reaction gas injection process is selected from the group consisting of O₂, H₂O, O₃, and a mixture thereof.

15. The method of claim 8, wherein the high-k layer is formed of selected from the group consisting of Al₂O₃, HfO₂, ZrO₂, SiON, La₂O₃, Y₂O₃, TiO₂, CeO₂, N₂O₃, Ta₂O₅, BaTiO₃, SrTiO₃, BST, and PZT, or by stacking two or more thereof

16. The method of claim 8, wherein the plasma treatment process is a plasma oxidization process employing a radical.

17. The method of claim 16, wherein the plasma oxidization process is performed using a mixed gas of an Ar gas and an O₂ gas.

18. The method of claim 17, wherein a H₂ gas is further added to the mixed gas.

19. The method of claim 16, wherein the plasma oxidization process is performed at a temperature of approximately 300 degrees Celsius to approximately 600 degrees Celsius under a pressure of approximately 0.01 Torr to approximately 10 Torr using a power of approximately 1 kW to approximately 5 kW.

20. The method of claim 8, wherein the first and third insulating layers each comprise an oxide layer having a thickness of approximately 20 angstroms to approximately 50 angstroms.

21. The method of claim 20, wherein forming each of the first and third insulating layers comprises performing a low-pressure chemical vapor deposition (LP-CVD) method at a temperature range approximately 600 degrees Celsius to approximately 900 degrees Celsius.

22. The method of claim 20, wherein the oxide layer is comprises a dichlorosilane high temperature oxide (DCS-HTO) product of a reaction between SiCl₂H₂ and N₂O₂ gases.

23. A method of forming a dielectric layer of a semiconductor memory device, the method comprising:
forming a first insulating layer on a semiconductor substrate;
forming a second insulating layer on the first insulating layer, the second insulating layer comprises a high-k material; and
forming a third insulating layer on the second insulating layer.

24. The method of claim 23, further comprising performing a plasma treatment process at a temperature less than a temperature at which the second insulating layer would crystallize, to make a surface of the second insulating layer uniform, prior to forming the third insulating layer.
